(19) United States
(12) Patent Application Publication
(10) Pub. No.: US 2024/0258186 A1
(43) Pub. Date: Aug. 1, 2024

(54) SEMICONDUCTOR DEVICE

(71) Applicant: Rohm Co., Ltd., Kyoto-shi (JP)

(72) Inventors: Ryotaro KAKIZAKI, Kyoto-shi (JP); Koshun SAITO, Kyoto-shi (JP)

(21) Appl. No.: 18/630,486

(22) Filed: Apr. 9, 2024

Related U.S. Application Data
(63) Continuation of application No. PCT/JP2022/042650, filed on Nov. 17, 2022.

(30) Foreign Application Priority Data
Dec. 1, 2021 (JP) 2021-195176

(51) Int. Cl. H01L 23/31; H01L 23/00; H01L 23/495

(52) U.S. Cl. CPC H01L 23/3121; H01L 23/49555; H01L 24/45; H01L 24/48; H01L 23/49513; H01L 24/06; H01L 24/29; H01L 24/32; H01L 24/46; H01L 24/49; H01L 24/73; H01L 2224/0603; H01L 2224/06051; H01L 2224/06181; H01L 2224/29139; H01L 2224/32245; H01L 2224/45124; H01L 2224/45144; H01L 2224/45147; H01L 2224/46; H01L 2224/48091; H01L 2224/48247; H01L 2224/49052; H01L 2224/49112; H01L 2224/73265; H01L 2924/10253; H01L 2924/10272; H01L 2924/13055; H01L 2924/13091

(57) ABSTRACT

A semiconductor device includes a semiconductor element, a conductor, and a sealing resin. The conductor includes a die pad, a first terminal, and a second terminal. The sealing resin covers a portion of the conductor and the semiconductor element. The sealing resin includes first, second, third and fourth resin surfaces. The die pad includes a first-lead obverse surface with the semiconductor element mounted, and a first-lead reverse surface exposed from the second resin surface. The first terminal is bent in a first sense of z direction and exposed from the third resin surface. The second terminal is bent in the first sense of z direction and exposed from the fourth resin surface. The first resin surface includes a recessed region recessed in z direction toward the second resin surface. As viewed in z direction, the recessed region overlaps with an imaginary line connecting the first terminal and the second terminal.

### TECHNICAL FIELD

The present disclosure relates to semiconductor devices.

### BACKGROUND ART

JP-A-2017-174951 discloses an example of a semiconductor device that includes: a first lead including a first pad having a pad obverse surface and a pad reverse surface; a second lead, a third lead, a semiconductor element mounted on the pad obverse surface, and a sealing resin in contact with the pad obverse surface and covering the semiconductor element. The first lead, the second lead, and the third lead respectively have a first terminal, a second terminal, and a third terminal that extend in the same direction. The semiconductor device is mounted onto a circuit board or the like by inserting the first terminal, the second terminal, and the third terminal into through holes formed in the circuit board. When the semiconductor device is attached to a heat sink, an insulating sheet or the like is disposed between the pad reverse surface and the heat sink.

### BRIEF DESCRIPTION OF THE DRAWINGS

FIG. 1 is a perspective view of a semiconductor device according to a first embodiment of the present disclosure.

FIG. 2 is a perspective view of the semiconductor device according to the first embodiment of the present disclosure.

FIG. 3 is a perspective view of the semiconductor device according to the first embodiment of the present disclosure.

FIG. 4 is a perspective view showing relevant portions of the semiconductor device according to the first embodiment of the present disclosure.

FIG. 5 is a perspective view showing relevant portions of the semiconductor device according to the first embodiment of the present disclosure.

FIG. 6 is a plan view of the semiconductor device according to the first embodiment of the present disclosure.

FIG. 7 is a bottom view of the semiconductor device according to the first embodiment of the present disclosure.

FIG. 8 is a front view of the semiconductor device according to the first embodiment of the present disclosure.

FIG. 9 is a plan view showing relevant portions of the semiconductor device according to the first embodiment of the present disclosure.

FIG. 10 is a plan view showing relevant portions of the semiconductor device according to the first embodiment of the present disclosure.

FIG. 11 is a sectional view taken along line XI-XI in FIG. 10.

FIG. 12 is a sectional view taken along line XII-XII in FIG. 10.

FIG. 13 is a sectional view taken along line XIII-XIII in FIG. 10.

FIG. 14 is a sectional view taken along line XIV-XIV in FIG. 10.

FIG. 15 is a sectional view taken along line XV-XV in FIG. 10.

FIG. 16 is a sectional view taken along line XVI-XVI in FIG. 10.

FIG. 17 is a sectional view showing the semiconductor device in a state of use according to the first embodiment of the present disclosure.

FIG. 18 is a perspective view of a semiconductor device according to a first variation of the first embodiment of the present disclosure.

FIG. 19 is a sectional view corresponding to FIG. 11, showing the semiconductor device according to the first variation of the first embodiment of the present disclosure.

FIG. 20 is a perspective view of a semiconductor device according to a second variation of the first embodiment of the present disclosure.

FIG. 21 is a sectional view corresponding to FIG. 11, showing the semiconductor device according to the second variation of the first embodiment of the present disclosure.

FIG. 22 is a sectional view corresponding to FIG. 11, showing a semiconductor device according to a third variation of the first embodiment of the present disclosure.

FIG. 23 is a sectional view corresponding to FIG. 11, showing a semiconductor device according to a fourth variation of the first embodiment of the present disclosure.

FIG. 24 is a perspective view showing relevant portions of a semiconductor device according to a fifth variation of the first embodiment of the present disclosure.

FIG. 25 is a sectional view corresponding to FIG. 11, showing the semiconductor device according to the fifth variation of the first embodiment of the present disclosure.

FIG. 26 is a perspective view showing relevant portions of a semiconductor device according to a sixth variation of the first embodiment of the present disclosure.

FIG. 27 is a plan view showing relevant portions of a semiconductor device according to a second embodiment of the present disclosure.

FIG. 28 is a bottom view of the semiconductor device according to the second embodiment of the present disclosure.

FIG. 29 is a front view of the semiconductor device according to the second embodiment of the present disclosure.

FIG. 30 is a sectional view corresponding to FIG. 11, showing the semiconductor device according to the second embodiment of the present disclosure.

FIG. 31 is a sectional view corresponding to FIG. 13, showing the semiconductor device according to the second embodiment of the present disclosure.

FIG. 32 is a bottom view of a semiconductor device according to a third embodiment of the present disclosure.

FIG. 33 is a sectional view corresponding to FIG. 13, showing the semiconductor device according to the third embodiment of the present disclosure.

FIG. 34 is a sectional view corresponding to FIG. 13, showing a semiconductor device according to a variation of the third embodiment of the present disclosure.

FIG. 35 is a bottom view of a semiconductor device according to a fourth embodiment of the present disclosure.

### DETAILED DESCRIPTION OF EMBODIMENTS

The following describes preferred embodiments of the present disclosure in detail with reference to the drawings.

In the present disclosure, the terms such as “first”, “second”, “third”, and so on are used merely as labels and not intended to order the items modified by the terms.

In the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a portion of the object B”. Still further, “A surface A faces in a direction B (or a first sense or a second sense of the direction B) is not limited, unless otherwise specifically noted, to the situation where the surface A forms an angle of 90° with the surface B but includes the situation where the surface A is inclined with respect to the surface B. Still further, “An object A is perpendicular to an object B (or a direction B)” is not limited, unless otherwise specifically noted, to the situation where the angle formed by the object A with the object B (the direction B) is strictly 90° but includes the situation where the angle is approximately 90° (within a range allowing for errors due to, for example, manufacturing tolerances). Still further, “An object A is parallel to an object B (a direction B)” is not limited, unless otherwise specifically noted, to the situation where the object A is strictly parallel to the object B (the direction B) but includes the situation where the object A is substantially parallel to the object B (the direction B) (within a range allowing for errors due to, for example, manufacturing tolerances).

### First Embodiment

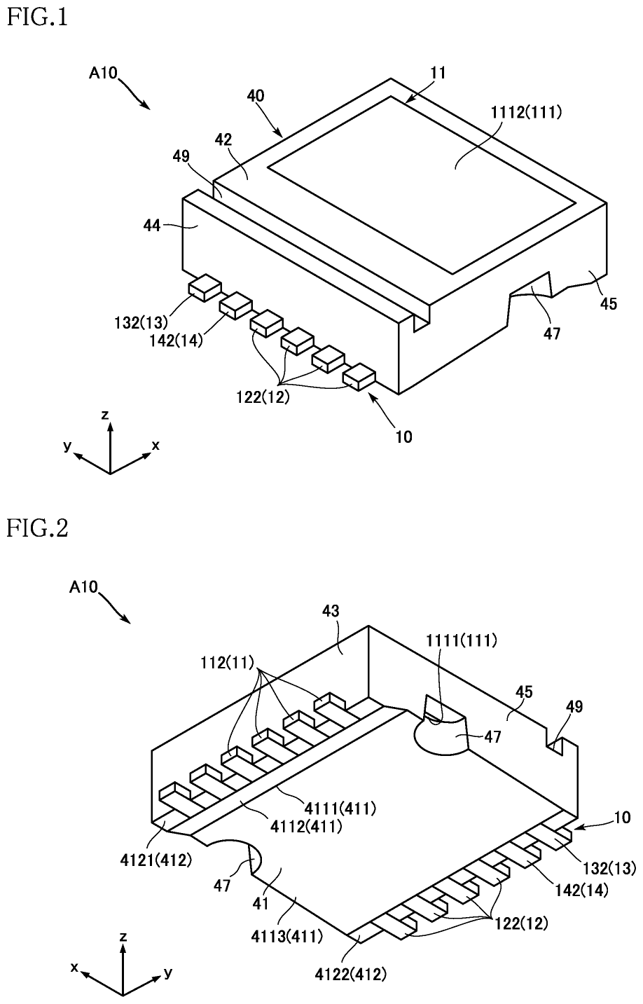

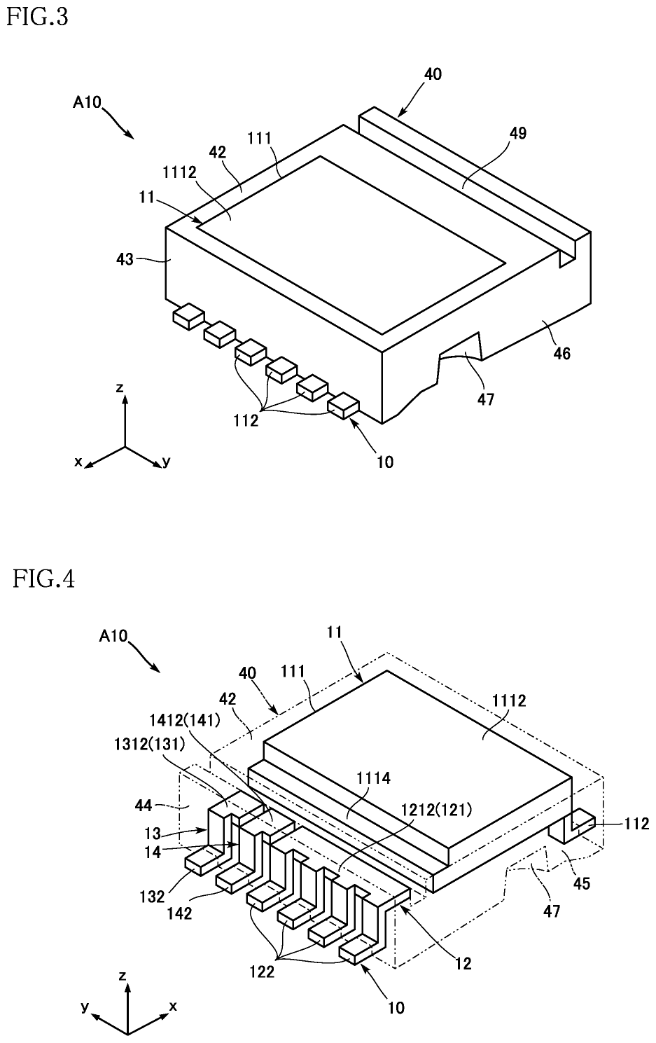

FIGS. 1 to 17 show a semiconductor device according to a first embodiment of the present disclosure. The semiconductor device A10 of the present embodiment includes a conductive member 10, a semiconductor element 20, a plurality of connecting members 31, 32, and 33, and a sealing resin 40. In these figures, the z direction is an example of a thickness direction, and the x direction is an example of a first direction, and the y direction is an example of a second direction.

### Conductive Member 10:

The conductive member 10 forms a conductive path to the semiconductor element 20. The conductive member 10 of the present embodiment includes a first lead 11, a second lead 12, a third lead 13, and a fourth lead 14. The first lead 11, the second lead 12, the third lead 13, and the fourth lead 14 are made of a suitable material, including but not limited to copper (Cu) and a copper alloy. In addition, appropriate portions of the first lead 11, the second lead 12, the third lead 13, and the fourth lead 14 (for example, portions exposed from the sealing resin 40) may be plated with silver (Ag), nickel (Ni), or tin (Sn), for example.

### First Lead 11:

As shown in FIGS. 1 to 17, the first lead 11 includes a die pad portion 111 and a plurality of first terminal portions 112. The die pad portion 111 has a first-lead obverse surface 1111, a first-lead reverse surface 1112, and a first-lead side surface 1113. The first-lead obverse surface 1111 faces in a first sense of the z direction, and the first-lead reverse surface 1112 faces in a second sense of the z direction. The first-lead obverse surface 1111 is where the semiconductor element 20 is mounted. The first-lead reverse surface 1112 is exposed from the sealing resin 40 (a second resin surface 42 described later). That is, the first-lead obverse surface 1111 of the die pad portion 111 is a mounting surface for the semiconductor element 20, and the first-lead reverse surface 1112 is an exposed surface exposed from the sealing resin 40 (the second resin surface 42 described later).

The first-lead side surface 1113 is located between the first-lead obverse surface 1111 and the first-lead reverse surface 1112 in the z direction, facing in a first sense of the x direction. The shape of the first-lead side surface 1113 is not specifically limited. In the illustrated example, the first-lead side surface 1113 is rectangular as viewed in the x direction.

The die pad portion 111 of the present embodiment additionally has a first intermediate surface 1114. The first intermediate surface 1114 is located between the first-lead obverse surface 1111 and the first-lead reverse surface 1112 in the x direction, facing in the first sense of the z direction (the same direction in which the first-lead reverse surface 1112 faces). The first intermediate surface 1114 is covered with the sealing resin 40. The first intermediate surface 1114 forms a step in the die pad portion 111. This is effective for preventing unintentional detachment of the die pad portion 111 from the sealing resin 40. The die pad portion 111, however, may be without the first intermediate surface 1114.

The shape of the die pad portion 111 is not specifically limited. In the illustrated example, the die pad portion 111 is rectangular as viewed in the z direction. Also, the shapes of the first-lead obverse surface 1111 and the first-lead reverse surface 1112 are not specifically limited. In the illustrated example, the first-lead obverse surface 1111 and the first-lead reverse surface 1112 are rectangular as viewed in the z direction.

The first terminal portions 112 are arranged side by side in the y direction. Each first terminal portion 112 is bent toward the side in the first sense of the z direction. Each first terminal portion 112 includes a first section 1121, a second section 1122, and a third section 1123.

The first section 1121 is connected to the die pad portion 111. The first section 1121 may be integrally formed with the die pad portion 111 or joined to the die pad portion 111 by, for example, fusion welding, ultrasonic bonding, or using a conductive bonding material. The first section 1121 extends from the first-lead side surface 1113 of the die pad portion 111 in the first sense of the x direction. In the illustrated example, the first section 1121 is parallel to the x-y plane. In the illustrated example, the first section 1121 has the same (or substantially the same) length in the x direction as that of a sixth section 1223 in the x direction. The first section 1121, however, may be longer that. The shape of the first section 1121 is not specifically limited. In the illustrated example, the first section 1121 is rectangular as viewed in the z direction. In the present embodiment, the die pad portion 111 is larger than the first section 1121 in length in the z direction. The first section 1121 is spaced apart from the first-lead reverse surface 1112 in the z direction. In the illustrated example, the first section 1121 is in contact with the first-lead obverse surface 1111. The first section 1121 may have an imaginary surface that is flush with the first-lead obverse surface 1111. The first section 1121 is covered with the sealing resin 40. The first section 1121 is closer than the second section 1122 to the die pad portion 111 in the y direction.

The second section 1122 is located in the first sense of the z direction from the first section 1121. The second section 1122 protrudes from the side surface of the sealing resin 40 located in the first sense of the x direction (a third resin surface 43 described later) and is exposed from the bottom surface (a first resin surface 41 described later) of the sealing resin 40. The second section 1122 is used for mounting the semiconductor device A10 onto the surface of a circuit board or the like. The second section 1122 extends in the x direction. The second section 1122 is located farther than the first section 1121 from the die pad portion 111 in the x direction.

The third section 1123 is located between the first section 1121 and the second section 1122. The third section 1123 extends from the first section 1121 in the first sense of the z direction. In the illustrated example, the third section 1123 extends in the z direction and is perpendicular to each of the first section 1121 and the second section 1122. In another example, the third section 1123 may be inclined relative to the first section 1121 and the second section 1122. The third section 1123 is connected to the end of the first section 1121 in the first sense of the z direction and to the end of the second section 1122 in a second sense of the x direction. The shape of the third section 1123 is not specifically limited. In the illustrated example, the third section 1123 is rectangular as viewed in the x direction. The third section 1123 is covered with the sealing resin 40.

For each first terminal portion 112, the thickness of the first section 1121 (the length in the z direction), the thickness of the second section 1122 (the length in the y direction), and the thickness of the third section 1123 (the length in the z direction) are not specifically limited relative to each other. In the illustrated example, the respective thicknesses are the same (or substantially the same).

### Second Lead 12:

The second lead 12 is spaced apart from the first lead 11 (the die pad portion 111) in the second sense of the x direction. The second lead 12 includes a pad portion 121 and a plurality of second terminal portions 122.

The pad portion 121 has a second-lead obverse surface 1211 and a second-lead reverse surface 1212. The second-lead obverse surface 1211 faces in the first sense of the z direction. The second-lead reverse surface 1212 faces in the second sense of the z direction. The connecting member 31 is connected to the second-lead obverse surface 1211. The shape of the pad portion 121 is not specifically limited. In the illustrated example, the pad portion 121 is in a rectangle shape that is longer in the y direction. The pad portion 121 is smaller than the die pad portion 111 as viewed in the z direction. In addition, the size of the pad portion 121 in the z direction is smaller than that of the die pad portion 111 and the same as that of the first terminal portion 112.

The second terminal portions 122 are arranged side by side in the y direction. Each second terminal portion 122 is bent toward the side in the first sense of the z direction. Each second terminal portion 122 includes a fourth section 1221, a fifth section 1222, and a sixth section 1223.

The fourth section 1221 is connected to the pad portion 121. The fourth section 1221 is integrally formed with the pad portion 121. The fourth section 1221 extends from the pad portion 121 in the second sense of the x direction. In the illustrated example, the fourth section 1221 is parallel to the x-y plane. The shape of the fourth section 1221 is not specifically limited. In the illustrated example, the fourth section 1221 is rectangular as viewed in the z direction. The fourth section 1221 is covered with the sealing resin 40.

The fifth section 1222 is located in the first sense of the z direction from the fourth section 1221. The fifth section 1222 protrudes from the side surface of the sealing resin 40 located in the second sense of the x direction (a fourth resin surface 44 described later) and is exposed from the bottom surface (the first resin surface 41 described later) of the sealing resin 40. The fifth section 1222 is used for mounting the semiconductor device A10 onto the surface of a circuit board or the like. The fifth section 1222 extends in the x direction. The fifth section 1222 is located farther than the fourth section 1221 from the die pad portion 111 in the x direction.

The sixth section 1223 is located between the fourth section 1221 and the fifth section 1222. The sixth section 1223 extends from the fourth section 1221 in the first sense of the z direction. In the illustrated example, the sixth section 1223 extends in the z direction and is perpendicular to each of the fourth section 1221 and the fifth section 1222. In another example, the sixth section 1223 may be inclined relative to the fourth section 1221 and the fifth section 1222. The sixth section 1223 is connected to the end of the fourth section 1221 in the second sense of the x direction and to the end of the fifth section 1222 in the first sense of the x direction. The shape of the sixth section 1223 is not specifically limited. In the illustrated example, the sixth section 1223 is rectangular as viewed in the x direction. The sixth section 1223 is covered with the sealing resin 40.

For each second terminal portion 122, the thickness of the fourth section 1221 (the length in the z direction), the thickness of the fifth section 1222 (the length in the y direction), and the thickness of the sixth section 1223 (the length in the z direction) are not specifically limited relative to each other. In the illustrated example, the respective thicknesses are the same (or substantially the same). In addition, the thickness of the fifth section 1222 and the thickness of the second section 1122 are not limited relative to each other. In the illustrated example, the respective thicknesses are the same (or substantially the same).

### Third Lead 13:

The third lead 13 is spaced apart from the first lead 11 (the die pad portion 111) in the second sense of the x direction. The third lead 13 is aligned with the second leads 12 in the y direction. The third lead 13 includes a pad portion 131 and a third terminal portion 132.

The pad portion 131 has a third-lead obverse surface 1311 and a third-lead reverse surface 1312. The third-lead obverse surface 1311 faces in the first sense of the z direction. The third-lead reverse surface 1312 faces in the second sense of the z direction. The connecting member 32 is connected to the third-lead obverse surface 1311. The shape of the pad portion 131 is not specifically limited. In the illustrated example, the pad portion 131 is rectangular as viewed in the z direction. The pad portion 131 is smaller than the pad portion 121 as viewed in the z direction. In addition, the size of the pad portion 131 in the z direction is smaller than that of the die pad portion 111 and the same as that of the pad portion 121.

The third terminal portion 132 is bent toward the side in the first sense of the z direction. The third terminal portion 132 includes a seventh section 1321, an eighth section 1322, and a ninth section 1323.

The seventh section 1321 is connected to the pad portion 131. The seventh section 1321 is integrally formed with the pad portion 131. The seventh section 1321 extends from the pad portion 131 in the second sense of the x direction. In the illustrated example, the seventh section 1321 is parallel to the x-y plane. The shape of the seventh section 1321 is not specifically limited. In the illustrated example, the seventh section 1321 is rectangular as viewed in the z direction. The seventh section 1321 is covered with the sealing resin 40.

The eighth section 1322 is located in the first sense of the z direction from the seventh section 1321. The eighth section 1322 protrudes from the side surface of the sealing resin 40 located in the second sense of the x direction (the fourth resin surface 44 described later) and is exposed from the bottom surface (the first resin surface 41 described later) of the sealing resin 40. The eighth section 1322 is used for mounting the semiconductor device A10 onto the surface of a circuit board or the like. The eighth section 1322 extends in the x direction. The eighth section 1322 is located farther than the seventh section 1321 from the die pad portion 111 in the x direction.

The ninth section 1323 is located between the seventh section 1321 and the eighth section 1322. The ninth section 1323 extends from the seventh section 1321 in the first sense of the z direction. In the illustrated example, the ninth section 1323 extends in the z direction and is perpendicular to each of the seventh section 1321 and the eighth section 1322. In another example, the ninth section 1323 may be inclined relative to the seventh section 1321 and the eighth section 1322. The ninth section 1323 is connected to the end of the seventh section 1321 in the second sense of the x direction and to the end of the eighth section 1322 in the first sense of the x direction. The shape of the ninth section 1323 is not specifically limited. In the illustrated example, the ninth section 1323 is rectangular as viewed in the x direction. The ninth section 1323 is covered with the sealing resin 40.

For the third terminal portion 132, the thickness of the seventh section 1321 (the length in the z direction), the thickness of the eighth section 1322 (the length in the y direction), and the thickness of the ninth section 1323 (the length in the z direction) are not specifically limited relative to each other. In the illustrated example, the respective thicknesses are the same (or substantially the same). In addition, the thickness of the eighth section 1322 and the thickness of the fifth section 1222 are not limited relative to each other. In the illustrated example, the respective thicknesses are the same (or substantially the same).

### Fourth Lead 14:

The fourth lead 14 is spaced apart from the first lead 11 (the die pad portion 111) in the second sense of the x direction. The fourth lead 14 is located between the second leads 12 and the third lead 13 in the y direction. The fourth lead 14 includes a pad portion 141 and a fourth terminal portion 142.

The pad portion 141 has a fourth-lead obverse surface 1411 and a fourth-lead reverse surface 1412. The fourth-lead obverse surface 1411 faces in the first sense of the direction. The fourth-lead reverse surface 1412 faces in the second sense of the z direction. The connecting member 33 is connected to the fourth-lead obverse surface 1411. The shape of the pad portion 141 is not specifically limited. In the illustrated example, the pad portion 141 is rectangular as viewed in the z direction. As viewed in the z direction, the pad portion 141 is smaller than the pad portion 121 and about the same size as the pad portion 131. In addition, the size of the pad portion 141 in the z direction is smaller than that of the die pad portion 111 and the same as that of the pad portions 121 and 131.

The fourth terminal portion 142 is bent toward the side in the first sense of the z direction. The fourth terminal portion 142 includes a tenth section 1421, an eleventh section 1422, and a twelfth section 1423.

The tenth section 1421 is connected to the pad portion 141. The tenth section 1421 is integrally formed with the pad portion 141. The tenth section 1421 extends from the pad portion 141 in the second sense of the x direction. In the illustrated example, the tenth section 1421 is parallel to the x-y plane. The shape of the tenth section 1421 is not specifically limited. In the illustrated example, the tenth section 1421 is rectangular as viewed in the z direction. The tenth section 1421 is covered with the sealing resin 40.

The eleventh section 1422 is located in the first sense of the z direction from the tenth section 1421. The eleventh section 1422 protrudes from the side surface of the sealing resin 40 located in the second sense of the x direction (the fourth resin surface 44 described later) and is exposed from the bottom surface (the first resin surface 41 described later) of the sealing resin 40. The eleventh section 1422 is used for mounting the semiconductor device A10 onto the surface of a circuit board or the like. The eleventh section 1422 extends in the x direction. The eleventh section 1422 is located farther than the tenth section 1421 from the die pad portion 111 in the x direction.

The twelfth section 1423 is located between the tenth section 1421 and the eleventh section 1422. The twelfth section 1423 extends from the tenth section 1421 in the first sense of the z direction. In the illustrated example, the twelfth section 1423 extends in the z direction and is perpendicular to each of the tenth section 1421 and the eleventh section 1422. In another example, the twelfth section 1423 may be inclined relative to the tenth section 1421 and the eleventh section 1422. The twelfth section 1423 is connected to the end of the tenth section 1421 in the second sense of the x direction and to the end of the eleventh section 1422 in the first sense of the x direction. The shape of the twelfth section 1423 is not specifically limited. In the illustrated example, the twelfth section 1423 is rectangular as viewed in the x direction. The twelfth section 1423 is covered with the sealing resin 40.

For the fourth terminal portion 142, the thickness of the tenth section 1421 (the length in the z direction), the thickness of the eleventh section 1422 (the length in the y direction), and the thickness of the twelfth section 1423 (the length in the z direction) are not specifically limited relative to each other. In the illustrated example, the respective thicknesses are the same (or substantially the same). In addition, the thickness of the eleventh section 1422 and the thickness of the fifth section 1222 are not limited relative to each other. In the illustrated example, the respective thicknesses are the same (or substantially the same).

### Semiconductor Element 20:

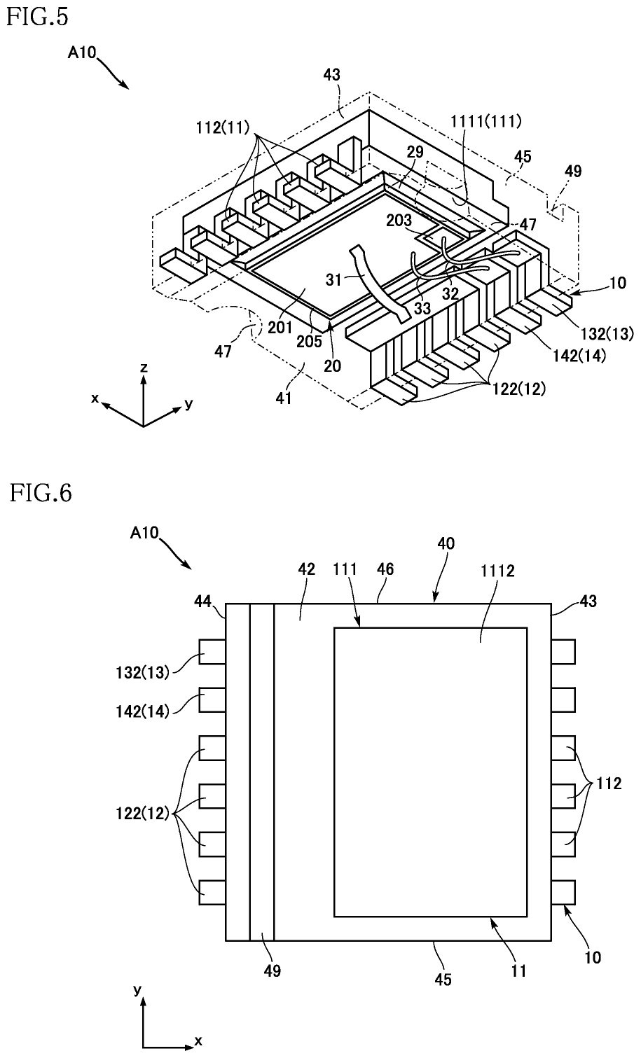

As shown in FIGS. 5, 10 to 14, and 17, the semiconductor element 20 is mounted on the first-lead obverse surface 1111 of the die pad portion 111. For the semiconductor device A10, the semiconductor element 20 is a switching element. In one example, the switching element is an n-channel, vertical type MOSFET (metal-oxide-semiconductor field-effect transistor). The semiconductor element 20, however, is not limited to a MOSFET. The semiconductor element 20 may be a different type of transistor, such as an IGBT (insulated gate bipolar transistor). In another example, the semiconductor element 20 may be a diode. The semiconductor element 20 includes a semiconductor layer 205, a first electrode 201, a second electrode 202, and a third electrode 203.

The semiconductor layer 205 includes a compound semiconductor substrate. The compound semiconductor substrate contains silicon carbide (Sic) as a main material. In a different example, the main material of the compound semiconductor substrate may be silico (Si).

The first electrode 201 is disposed on the side facing in the same direction as the first-lead obverse surface 1111 of the die pad portion 111 of the first lead 11 (on the side facing in the first sense of the z direction). The first electrode 201 corresponds to the source electrode of the semiconductor element 20.

The second electrode 202 is disposed opposite to the first electrode 201 in the z direction. The second electrode 202 faces the first-lead obverse surface 1111 of the die pad portion 111 of the first lead 11. The second electrode 202 corresponds to the drain electrode of the semiconductor element 20. In the present embodiment, the second electrode 202 is bonded to the first-lead obverse surface 1111 via a bonding layer 29. The bonding layer 29 may be a layer of solder, silver (Ag) paste, or sintered silver, for example.

The third electrode 203 is disposed on the same side as the first electrode 201 in the z direction and spaced apart from the first electrode 201. The third electrode 203 corresponds to the gate electrode of the semiconductor element 20. As viewed in the z direction, the third electrode 203 is smaller in area than the first electrode 201.

### Connecting Members 31, 32, and 33:

The connecting member 31 is bonded to the first electrode 201 of the semiconductor element 20 and the second-lead obverse surface 1211 of the pad portion 121 of the second lead 12. The connecting member 31 is made of a material including, without limitation, metals, such as aluminum (Al), copper (Cu), and gold (Au). In addition, the number of the connecting members 31 is not specifically limited, and a plurality of connecting members 31 may be provided. In the illustrated example, the connecting member 31 contains aluminum (Al) and is in the form of a flat strip. In another example, the connecting member 31 may be a thin thread (bonding wire).

The connecting member 32 is connected to the third electrode 203 of the semiconductor element 20 and the third-lead obverse surface 1311 of the pad portion 131 of the third lead 13. In illustrated example, the connecting member 32 contains gold (Au) and is in the form of a thread (bonding wire) thinner than the connecting member 31.

The connecting member 33 is connected to the first electrode 201 of the semiconductor element 20 and the fourth-lead obverse surface 1411 of the pad portion 141 of the fourth lead 14. In illustrated example, the connecting member 33 contains gold (Au) and is in the form of a thread (bonding wire) thinner than the connecting member 31.

In the present embodiment, the first terminal portions 112 of the first lead 11 are the drain terminals, the second terminal portions 122 of the second lead 12 are the source terminals, the third terminal portion 132 of the third lead 13 is the gate terminal, and the fourth terminal portion 142 of the fourth lead 14 is the source-sense terminal.

### Sealing Resin 40:

As shown in FIGS. 1 to 15, the sealing resin 40 covers the semiconductor element 20, the connecting members 31, 32, and 33, and a portion of each of the first lead 11, the second lead 12, the third lead 13, and the fourth lead 14. The sealing resin 40 is electrically insulating. The sealing resin 40 may be made of a material containing a black epoxy resin. The sealing resin 40 has the first resin surface 41, the second resin surface 42, the third resin surface 43, the fourth resin surface 44, the fifth resin surface 45, and the sixth resin surface 46.

The first resin surface 41 faces the same side as the first-lead obverse surface 1111 of the die pad portion 111 of the first lead 11 in the z direction (faces in the first sense of the z direction). The second resin surface 42 faces away from the first resin surface 41 in the z direction (faces in the second sense of the z direction). The first-lead reverse surface 1112 of the die pad portion 111 of the first lead 11 is exposed from the second resin surface 42. The second resin surface 42 and the first-lead reverse surface 1112 are flush with each other.

The third resin surface 43 faces in the first sense of the x direction. In the illustrated example, the first section 1121 of each first terminal portion 112 of the first lead 11 protrudes from the third resin surface 43 in the x direction. In a different example, each first section 1121 may have an end surface (the surface facing outward in the x direction) that is flush with the third resin surface 43.

The fourth resin surface 44 faces away from the third resin surface 43 in the x direction (faces in the second sense of the x direction). In the illustrated example, the fifth section 1222 of each second terminal portion 122 of the second lead 12 protrudes from the fourth resin surface 44 in the x direction, and the eighth section 1322 of the third terminal portion 132 of the third lead 13 and the eleventh section 1422 of the fourth terminal portion 142 of the fourth lead 14 also protrude from the fourth resin surface 44 in the x direction. In a different example, each of the fifth sections 1222, the eighth section 1322, and the eleventh section 1422 may have an end surface (the surface facing outward in the x direction) that is flush with the fourth resin surface 44.

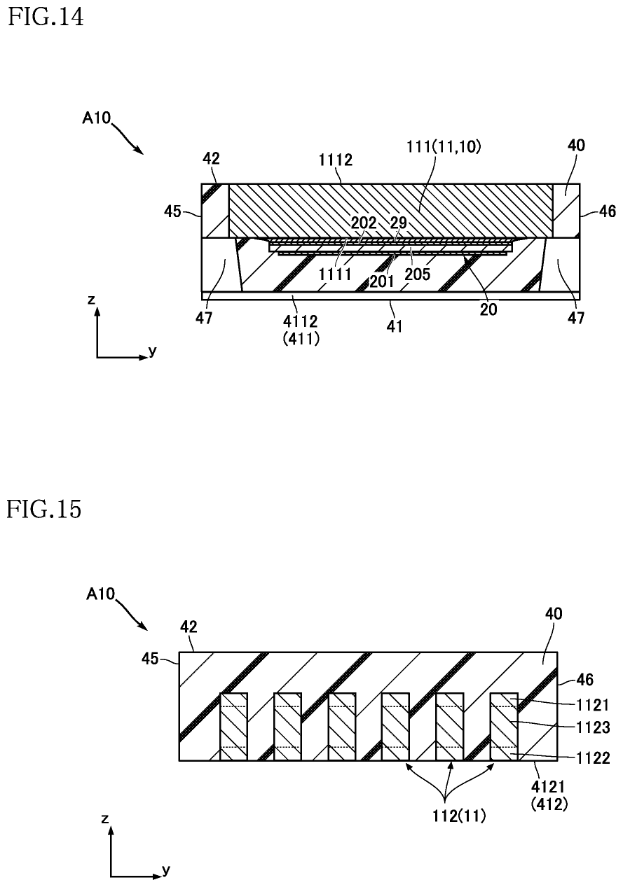

The fifth resin surface 45 faces in a first sense of the y direction. The sixth resin surface 46 faces away from the fifth resin surface 45 in the y direction (faces in a second sense of the y direction). While the fifth resin surface 45 and the sixth resin surface 46 are perpendicular to the y direction in the example shown in FIGS. 14 to 16, the fifth resin surface 45 and the sixth resin surface 46 may be inclined relative to the y direction. For example, the fifth resin surface 45 and the sixth resin surface 46 may be inclined such that the cross sectional area perpendicular to the z direction decrease from the first resin surface 41 to the second resin surface 42.

As shown in FIGS. 2, 7, 8, 11 to 13, and 17, the first resin surface 41 includes a recessed region 411 and an end region 412.

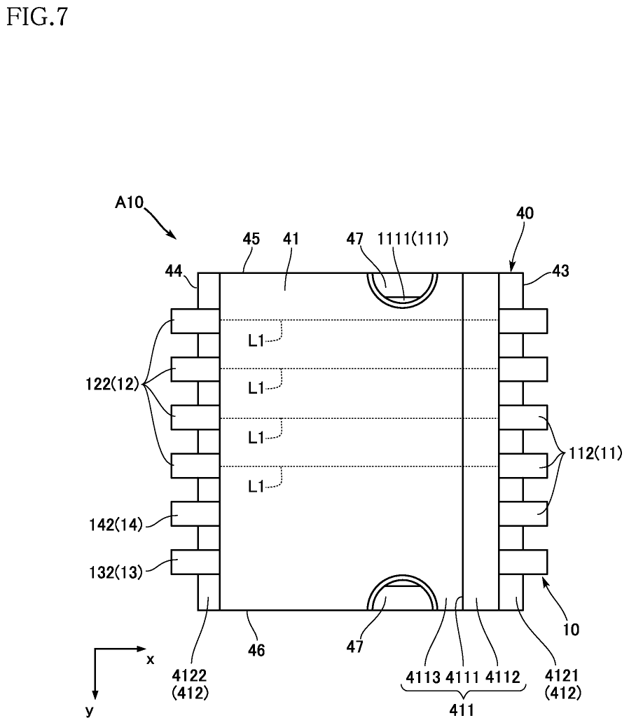

The recessed region 411 is a region in the first resin surface 41 recessed in the z direction toward the second resin surface 42. As shown in FIG. 7, the recessed region 411 overlaps with an imaginary line L1 connecting a first terminal portion 112 and a second terminal portion 122 as viewed in z direction. As shown in FIG. 7, in the present embodiment, the recessed region 411 overlaps with all of such imaginary lines L1 as viewed in z direction. In the illustrated example (see FIGS. 2 and 7), the recessed region 411 extends from the fifth resin surface 45 to the sixth resin surface 46 as viewed in the z direction.

As can be seen from the illustrated example, the recessed region 411 is a V-shaped groove. The recessed region 411 includes a valley 4111, a first slope 4112, and a second slope 4113.

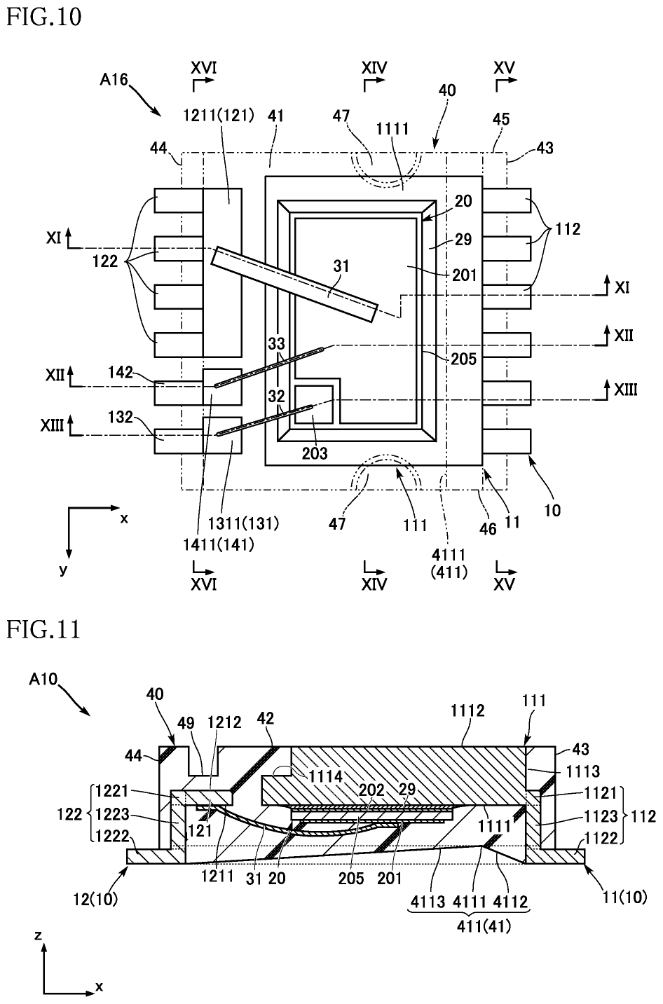

The valley 4111 extends linearly as viewed in the z direction. The valley 4111 is where the recessed region 411 is nearest to the second resin surface 42 in the z direction. That is, the valley 4111 is the deepest portion of the recessed region 411. The valley 4111 extends from the fifth resin surface 45 to the sixth resin surface 46. As shown in FIGS. 10 to 13, the valley 4111 (the deepest portion of the recessed region 411) does not overlap with any of the connecting members 31, 32, and 33 as viewed in the z direction. While the valley 4111 is offset in the first sense of the x direction (toward the first terminal portions 112) from the center of the sealing resin 40 in the x direction as viewed in z direction, this is a non-limiting example of the location of the valley 4111 in the x direction. While the valley 4111 is parallel (or substantially parallel) to the third resin surface 43 and the fourth resin surface 44 as viewed in the z direction, the valley 4111 may instead be inclined relative to the third resin surface 43 and the fourth resin surface 44.

The first slope 4112 meets the valley 4111 from the side in the first sense of the x direction, and the second slope 4113 meets the valley 4111 from the side in the second sense of the x direction. Each of the first slope 4112 and the second slope 4113 is inclined relative to the second resin surface 42 and the end region 412. The first slope 4112 is inclined such that the depth of the recessed region 411 increases with approach toward the valley 4111. The second slope 4113 is inclined such that the depth of the recessed region 411 increases with approach toward the valley 4111. In the illustrated example, the first slope 4112 is inclined at a greater angle than the second slope 4113 relative to the x-y plane. In a different example, one of the first slope 4112 and the second slope 4113 may be perpendicular to the x-y plane.

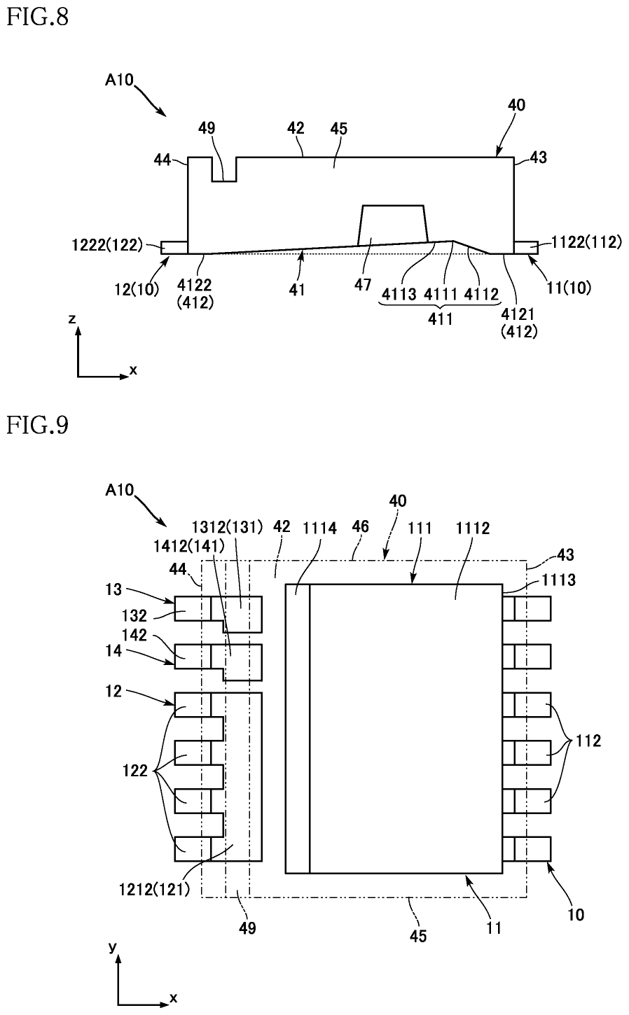

As shown in FIGS. 7 and 8, the end region 412 is located on either side of the recessed region 411 in the x direction. The end region 412 is flat. The end region 412 is parallel (or substantially parallel) to the second resin surface 42. The end region 412 includes a first region 4121 located in the first sense of the x direction from the recessed region 411 and a second region 4122 located in the second sense of the x direction from the recessed region 411.

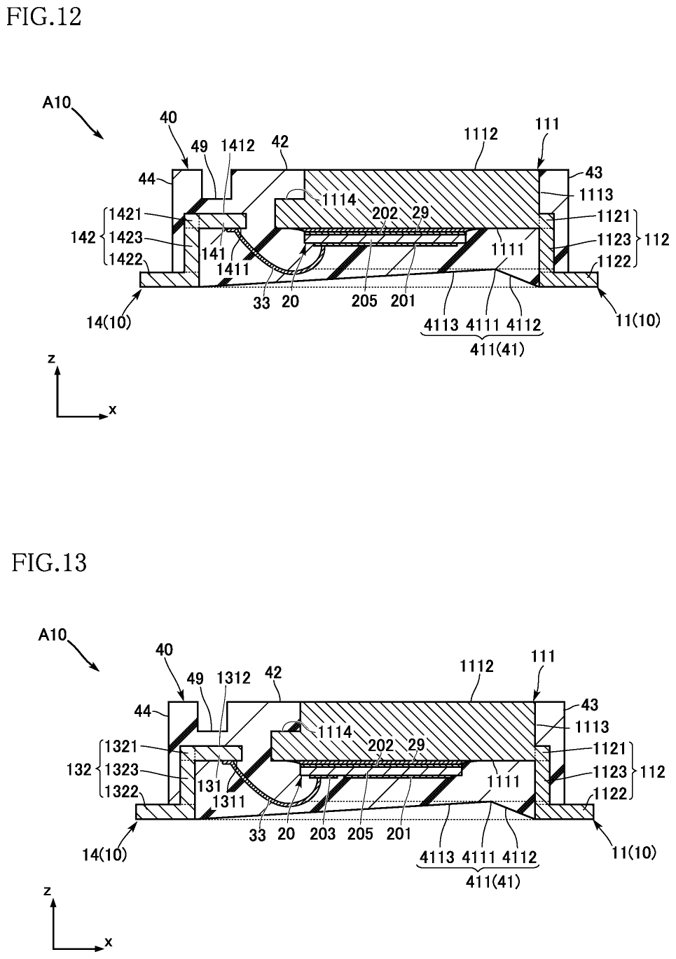

While the depth of the recessed region 411 at the deepest portion (the distance from the end region 412 to the valley 4111 in the z direction) is not specifically limited, in one example, the depth may be 10% or more and 20% or less of the length of the sealing resin 40 in the z direction. While the depth of the recessed region 411 at the deepest portion (the distance from the end region 412 to the valley 4111 in the z direction) is smaller than the distance from the connecting member 31 to the end region 412 in the z direction, it may be greater than that distance. While the depth of the recessed region 411 at the deepest portion (the distance from the end region 412 to the valley 4111 in the z direction) is greater than the distance from each of the connecting members 32 and 33 to the end region 412 in the z direction in the example shown in FIGS. 12 and 13, it may be smaller than that distance. The depth of the recessed region 411 at the deepest portion is greater than the thickness of each of the second section 1122 and the fifth section 1222 (the length in the z direction). In the semiconductor device A1, the top of each of the connecting members 32 and 33 in the first sense of the z direction is located farther in the first sense of the z direction than the top of the connecting member 31 in the first sense of the z direction. Alternatively, however, the top of the connecting member 31 may be located farther than the top of each of the connecting members 32 and 33 in the first sense of the z direction. The depth of the recessed region 411 at the deepest portion can be changed in view of the lengths of the connecting members 31, 32, and 33.

As shown in FIG. 15, the surface of each second section 1122 facing in the first sense of the z direction is exposed from the sealing resin 40 at the first region 4121. In the illustrated example, the surfaces of the second sections 1122 facing in the first sense of the z direction are flush with the first region 4121. Incidentally, the first terminal portions 112 may be plated to cover their surfaces exposed from the sealing resin 40. In which case, the surfaces of the second sections 1122 facing in the first sense of the z direction protrude from the first region 4121 in the first sense of the z direction due to the presence of the plating.

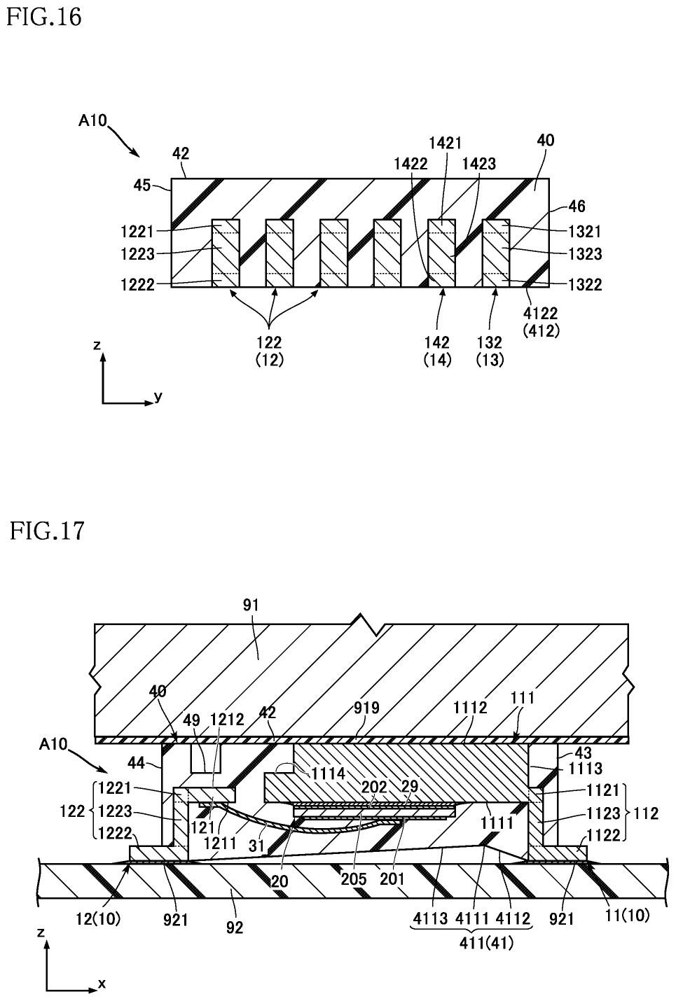

As shown in FIG. 16, the surface of each of the fifth sections 1222, the eighth section 1322, and the eleventh section 1422 facing in the first sense of the z direction is exposed from the sealing resin 40 at the second region 4122. In the illustrated example, the surfaces of the fifth sections 1222, the eighth section 1322, and the eleventh section 1422 facing in the first sense of the z direction are flush with the second region 4122. Incidentally, the second terminal portions 122, the third terminal portion 132, and the fourth terminal portion 142 may be plated to cover their surfaces exposed from the sealing resin 40. In which case, the surfaces of the fifth sections 1222, the eighth section 1322, and the eleventh section 1422 facing in the first sense of the z direction protrude from the second region 4122 in the first sense of the z direction due to the presence of the plating.

In the illustrated example, the sealing resin 40 includes a groove 49. The groove 49 is recessed from the second resin surface 42 in the z direction and extends in the y direction. The groove 49 extends to reach the fifth resin surface 45 and the sixth resin surface 46.

In the illustrated example, the sealing resin 40 has two recesses 47. One of the recesses 47 is recessed from the first resin surface 41 and the fifth resin surface 45. The other recess 47 is recessed from the first resin surface 41 and the sixth resin surface 46. In the illustrated example, portions of the first-lead obverse surface 1111 are exposed at the recesses 47. In a different example, the first-lead obverse surface 1111 is not exposed at the recesses 47. The two recesses 47 may be used as a guide for determining the orientation of the terminals in the semiconductor device A10 or used for carrying (gripping) the semiconductor device A10 in a manufacture or mounting process.

FIG. 17 shows the semiconductor device A10 in a state of use. In this example, the semiconductor device A10 is attached to a circuit board 92 by surface mounting. That is, the semiconductor device A10 is mounted by bonding and electrically connecting the second sections 1122 of the first terminal portions 112, the fifth sections 1222 of the second terminal portions 122, the eighth section 1322 of the third terminal portion 132, and the eleventh section 1422 of the fourth terminal portion 142 to the wiring pattern (not shown) of the circuit board 92 with solder 921, for example. Additionally, a heat sink 91 is placed to face the first-lead reverse surface 1112 of the die pad portion 111. In the illustrated example, a sheet material 919 is interposed between the first-lead reverse surface 1112 and the heat sink 91. The sheet material 919 may be an insulating sheet, for example.

The following describes the operation of the semiconductor device A10.

As shown in FIG. 17, the first-lead reverse surface 1112 is exposed from the second resin surface 42. This allows the heat sink 91 or the like to be attached to face the first-lead reverse surface 1112. Additionally, each of the first terminal portions 112 and the second terminal portions 122 is bent toward the side in the first sense of the z direction. The semiconductor device A10 is thus surface mountable to the circuit board 92 or the like. Additionally, the first terminal portions 112 protrude from the third resin surface 43, and the second terminal portions 122 protrude from the fourth resin surface 44. The first resin surface 41 includes the recessed region 411, and the recessed region 411 as viewed in the z direction overlaps with the imaginary lines L1 each connecting a first terminal portion 112 and a second terminal portion 122. This serves to increase each creepage distance between a first terminal portion 112 and a second terminal portion 122 along the first resin surface 41. Consequently, unintentional shorting between a first terminal portion 112 and a second terminal portion 122 can be prevented.

The third section 1123 is perpendicular to the first section 1121 and the second section 1122 (parallel to the z direction). This allows the length of the semiconductor device A10 to be reduced in the x direction. Similarly, the sixth section 1223 is perpendicular to the fourth section 1221 and the fifth section 1222 (parallel to the z direction), allowing the length of the semiconductor device A10 to be reduced in the x direction.

The length of the first section 1121 in the x direction is the same (or substantially the same) as the thickness (the length in the x direction) of the third section 1123. This configuration is effective for minimizing the length of the section 1121 and thus reducing the length of the first semiconductor device A10 in the x direction. Similarly, the length of the fourth section 1221 in the x direction is the same (or substantially the same) as the thickness (the length in the x direction) of the sixth section 1223. This is effective for minimizing the length of the fourth section 1221 in the x direction and thus reducing the length of the semiconductor device A10 in the x direction.

The second section 1122 is exposed at the first resin surface 41 (the first region 4121 of the end region 412). That is, a portion of the second section 1122 is disposed inside the third resin surface 43 of the sealing resin 40 in the x direction, allowing the length of the semiconductor device A10 to be reduced in the x direction. Similarly, the fifth section 1222 is exposed at the first resin surface 41 (the second region 4122 of the end region 412). That is, a portion of the fifth section 1222 to be disposed inside the fourth resin surface 44 of the sealing resin 40 in the x direction, allowing the length of the semiconductor device A10 to be reduced in the x direction. Note that the separation distance between a first terminal portion 112 and a second terminal portion 122 in the x direction is shorter when the second section 1122 and the fifth section 1222 are exposed at the first resin surface 41. In view of this, providing the recessed region 411 in the first resin surface 41 to increase the creepage distance is effective for prevent unintentional shorting between the first terminal portion 112 and the second terminal portion 122. That is, the semiconductor device A10 can be reduced in length in the x direction and keep an appropriate creepage distance between the first terminal portion 112 and the second terminal portion 122 along the first resin surface 41.

The deepest portion (the valley 4111) of the recessed region 411 does not overlap with any of the connecting members 31, 32, and 33 as viewed in the z direction. With this configuration, an appropriate distance is provided from the connecting members 31, 32, and 33 to the first resin surface 41 in the z direction, and thus the dielectric strength of the semiconductor device A10 is increased. In addition, as the deepest portion (the valley 4111) of the recessed region 411 does not overlap with any of the connecting members 31, 32, and 33 as viewed in the z direction, the recessed region 411 can be configured such that the depth at the deepest portion (the distance between the end region 412 to the valley 4111 in the z direction) is greater than the distance from the connecting members 31, 32, and 33 to the end region 412 in the z direction.

The depth of the recessed region 411 at the deepest portion (the distance from the end region 412 to the valley 4111 in the z direction) is greater than the distance from each of the connecting members 32 and 33 to the end region 412 in the z direction. This serves to sufficiently increase each creepage distance between a first terminal portion 112 and a second terminal portion 122 along the first resin surface 41. Incidentally, each creepage distance between a first terminal portion 112 and a second terminal portion 122 along the first resin surface 41 can be further increased by increasing the depth of the recessed region 411 at the deepest portion (the distance from the end region 412 to the valley 4111 in the z direction) to a depth greater than the distance between the connecting member 31 to the end region 412.

The depth of the recessed region 411 at the deepest portion (the distance from the end region 412 to the valley 4111 in the z direction) is greater than the thickness (the length in the z direction) of each of the second section 1122 and the fifth section 1222. This serves to sufficiently increase the creepage distance between the first terminal portion 112 and the second terminal portion 122 along the first resin surface 41.

The die pad portion 111 is larger than the first section 1121 in length in the z direction. Consequently, heat transferred from the semiconductor element 20 can spread to a wider region in the x and y directions before reaching the first-lead reverse surface 1112. Thus, the heat dissipation efficiency is improved as the heat from the semiconductor element 20 can be released to the heat sink 91 or the like through a wider region of the die pad portion 111.

The sealing resin 40 is formed with the groove 49. The groove 49 serves to increase the creepage distance from the first-lead reverse surface 1112 to the second lead 12 (the fourth sections 1221), the third lead 13 (the seventh section 1321), and the fourth lead 14 (the tenth section 1421) along the surface of the sealing resin 40.

In an example in which the semiconductor element 20 is an MOSFET (switching element), the first terminal portions 112 are the drain terminals and the second terminal portions 122 are the source terminals. In such a case, a large difference is expected between the potential at the first terminal portions 112 and the potential at the second terminal portions 122. Providing the recessed region 411 to increase each creepage distance between a first terminal portion 112 and a second terminal portion 122 along the first resin surface 41 effective for preventing is therefore unintentional shorting between a first terminal portion 112 and the second terminal portion 122.

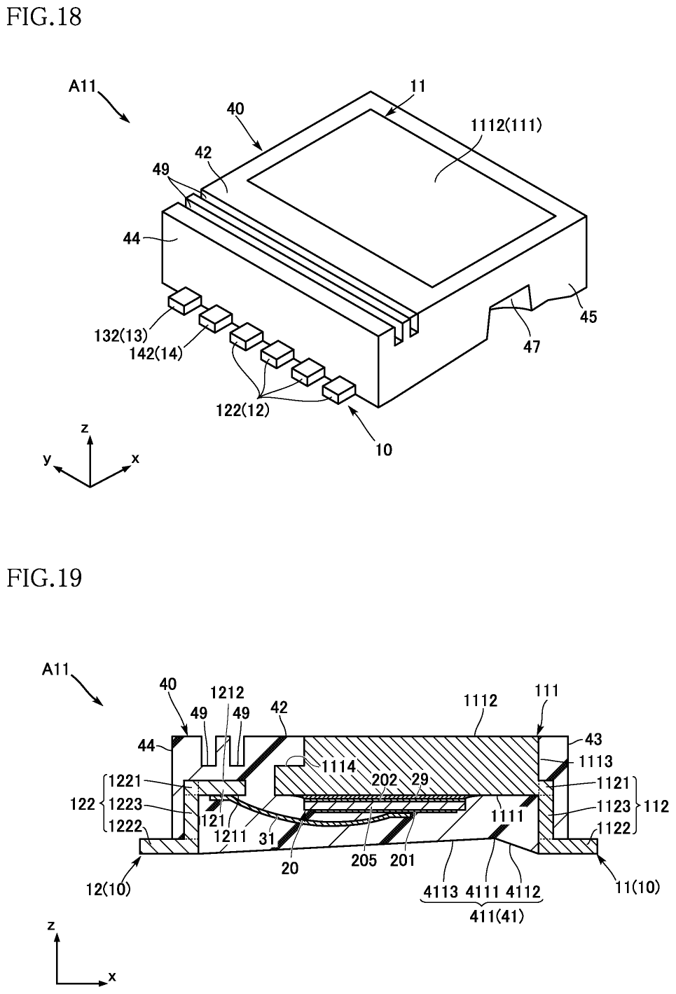

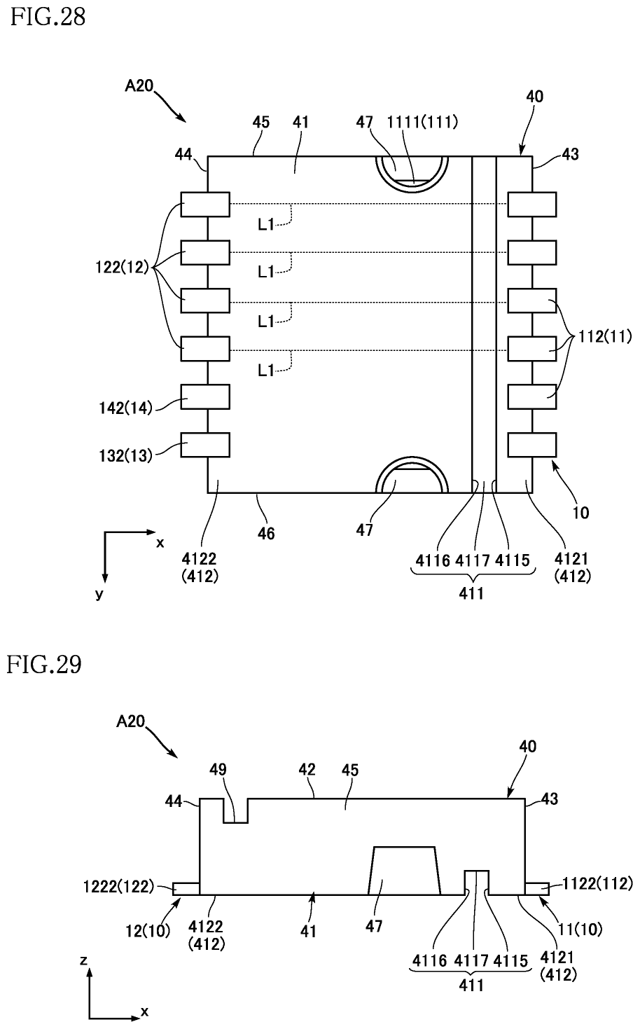

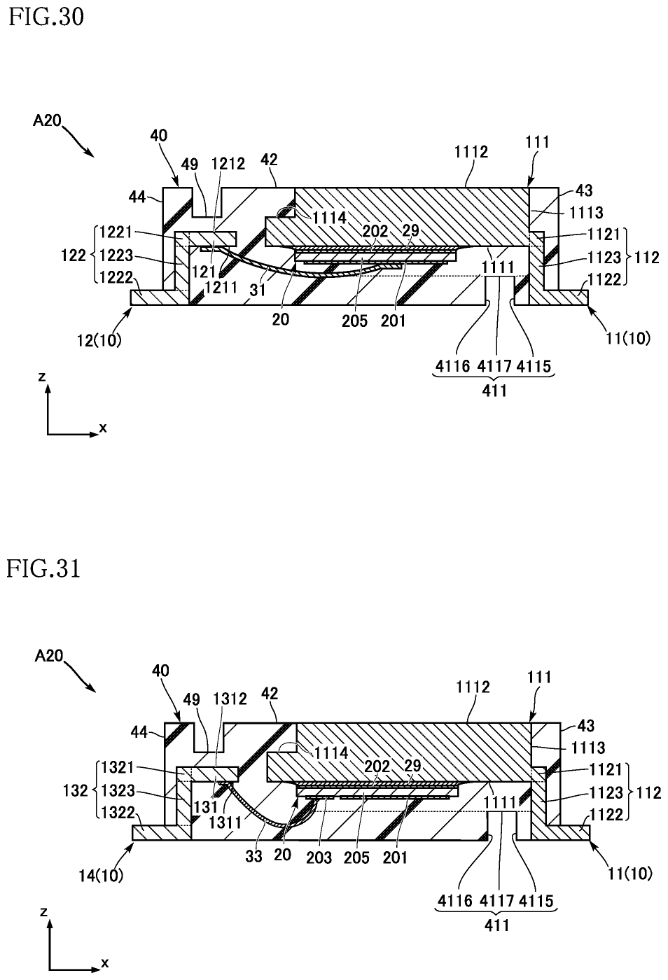

FIGS. 18 to 35 show other embodiments of the present disclosure. In these figures, the elements identical or similar to those of the above embodiment are denoted by the same reference numerals. In addition, the configuration of each part of any embodiment or variation can be combined unless a technical contradiction arises.

### First Variation of First Embodiment

FIGS. 18 and 19 show a first variation of the semiconductor device A10. A semiconductor device A11 according to the present variation includes a sealing resin 40 that is provided with two grooves 49.

The grooves 49 extend in the y direction, reaching the fifth resin surface 45 and the sixth resin surface 46. The two grooves 49 are spaced apart from each other in the x direction.

The semiconductor device A11 according to the present variation is surface mountable and achieves the same effect as the embodiment described above. In addition, the presence of the two grooves 49 serves to further increase the creepage distance from the first-lead reverse surface 1112 to the second terminal portions 122, the third terminal portion 132 and the fourth terminal portion 142. As the present variation indicates, the number of grooves 49 to be provided is not limited to a specific number.

### Second Variation of First Embodiment

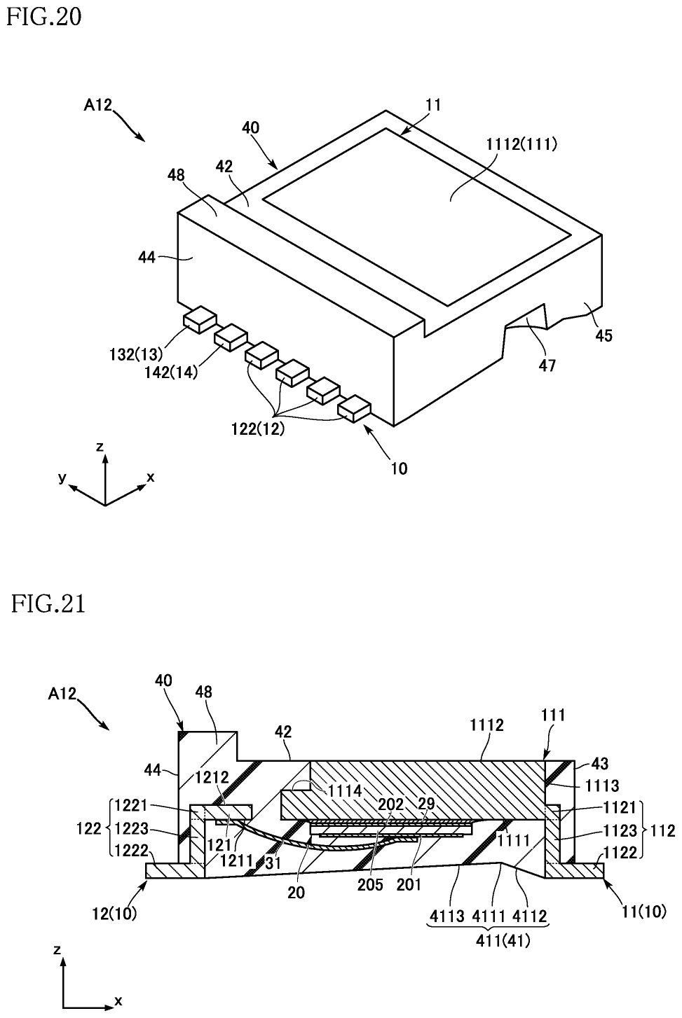

FIGS. 20 and 21 show a second variation of the semiconductor device A10. A semiconductor device A12 according to the present variation includes a sealing resin 40 that is provided with a protrusion 48.

The protrusion 48 protrudes from the second resin surface 42 in the second sense of the z direction. The protrusion 48 extends in the y direction, reaching the fifth resin surface 45 and the sixth resin surface 46. In the illustrated example, the protrusion 48 is located along the edge of the sealing resin 40 in the second sense of the x direction and thus in contact with the fourth resin surface 44.

The semiconductor device A12 according to the present variation is surface mountable. In addition, the presence of the protrusion 48 serves to increase the creepage distance from the first-lead reverse surface 1112 to the second terminal portions 122, the third terminal portion 132 and the fourth terminal portion 142.

### Third Variation of First Embodiment

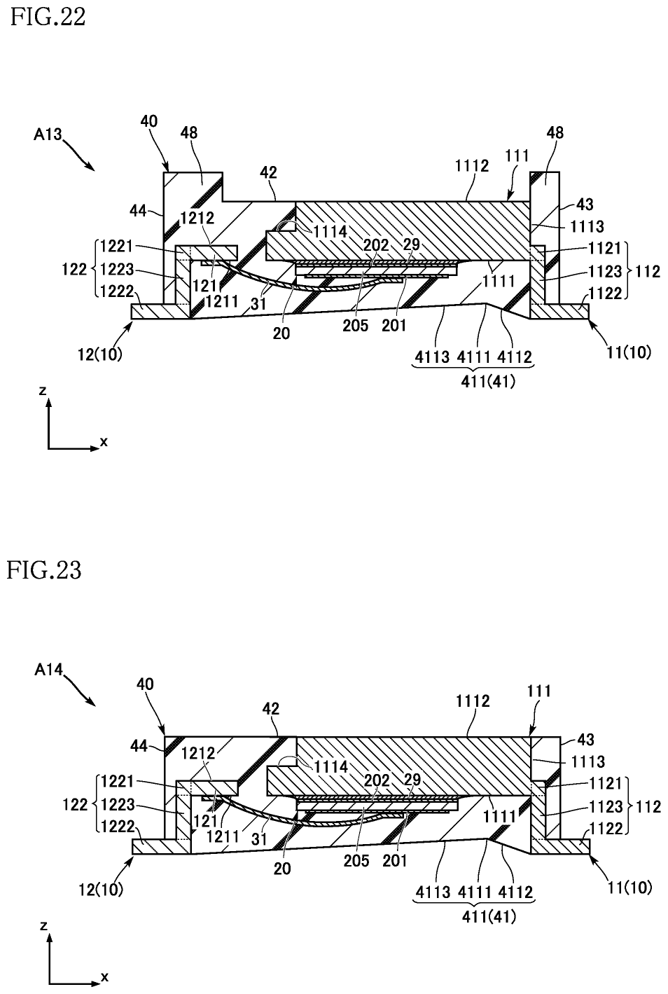

FIG. 22 shows a third variation of the semiconductor device A10. A semiconductor device A13 according to the present variation includes a sealing resin 40 that is provided with two protrusions 48.

Each protrusion 48 protrudes in the second sense of the z direction. Each protrusion 48 extends in the y direction, reaching the fifth resin surface 45 and the sixth resin surface 46. The two protrusions 48 are spaced apart from each other across the first-lead reverse surface 1112 in the x direction. One of the protrusions 48 is in contact with the fourth resin surface 44, and the other with the third resin surface 43.

The semiconductor device A13 according to the present variation is surface mountable. In addition, the presence of the two protrusions 48 serves to further increase the creepage distance from the first-lead reverse surface 1112 to the first terminal portions 112, the third terminal portion 132, and the fourth terminal portion 142. As the present variation indicates, the number of protrusions 48 to be provided is not specifically limited.

### Fourth Variation of First Embodiment

FIG. 23 shows a fourth variation of the semiconductor device A10. A semiconductor device A14 according to the present variation includes a sealing resin 40 without the protrusions 48 or the grooves 49 described above.

The semiconductor device A14 according to the present variation is surface mountable. As the present variation indicates, the sealing resin 40 may not have any protrusion 48 or groove 49.

### Fifth Variation of First Embodiment

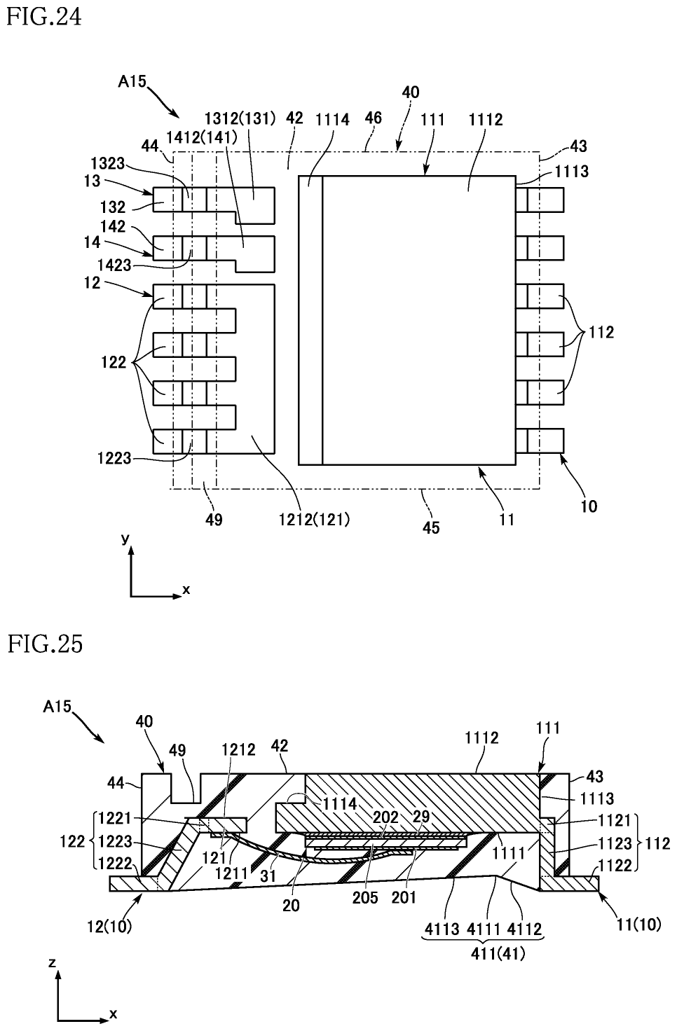

FIGS. 24 and 25 show a fifth variation of the semiconductor device A10. A semiconductor device A15 according to the present variation is such that the sixth section 1223 of each second terminal portion 122, the ninth section 1323 of the third terminal portion 132, and the twelfth section 1423 of the fourth terminal portion 142 are inclined relative to the z direction (the x-y plane).

The semiconductor device A15 according to the present variation is surface mountable. As the present variation indicates, the sixth section 1223 of each second terminal portion 122 can be either perpendicular or inclined relative to the fourth section 1221 and the fifth section 1222. Similarly, the ninth section 1323 of the third terminal portion 132 can be either perpendicular or inclined relative to the seventh section 1321 and the eighth section 1322, and the twelfth section 1423 of the fourth terminal portion 142 can be either perpendicular or inclined relative to the tenth section 1421 and the eleventh section 1422.

In the semiconductor device A15, the sixth sections 1223, the ninth section 1323, and the twelfth section 1423 are inclined. Alternatively or additionally, the third section 1123 of each first terminal portion 112 may be inclined relative to the first section 1121 and the second section 1122.

### Sixth Variation of First Embodiment

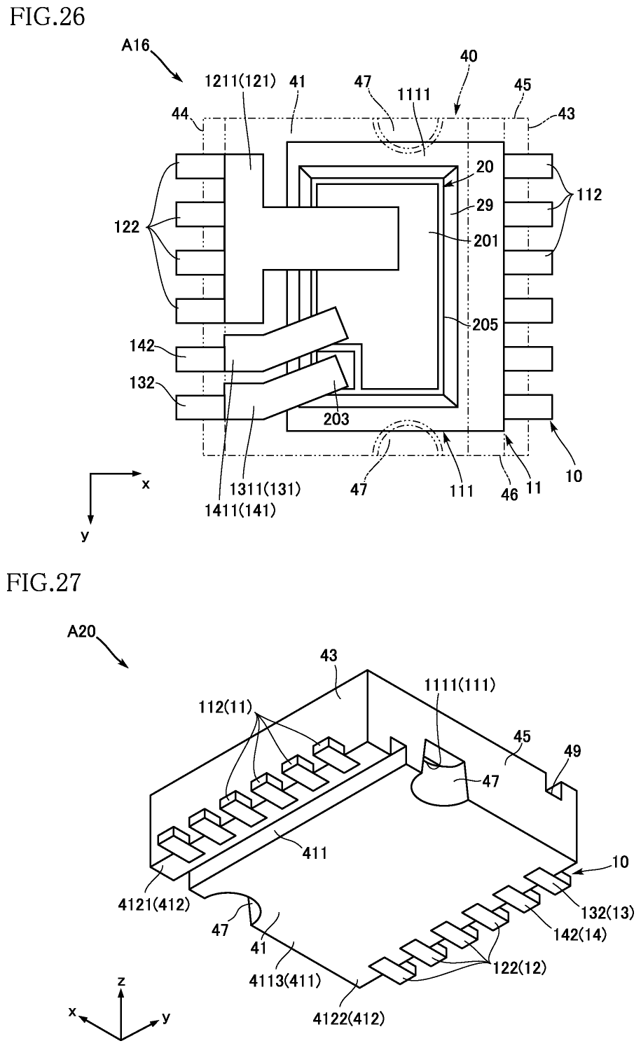

FIG. 26 shows a sixth variation of the semiconductor device A10. A semiconductor device A16 according to the present variation is not provided with the connecting members 31, 32, and 33 described above.

In the present variation, the second lead 12 includes a pad portion 121 with a second-lead reverse surface 1212 bonded and electrically connected to the first electrode 201 of the semiconductor element 20. The third lead 13 includes a pad portion 131 with a third-lead reverse surface 1312 bonded and electrically connected to the third electrode 203 of the semiconductor element 20. The fourth lead 14 includes a pad portion 141 with a fourth-lead reverse surface 1412 bonded and electrically connected to the first electrode 201 of the semiconductor element 20.

The semiconductor device A16 according to the present variation is surface mountable. As the present variation indicates, the configuration for electrically connecting the second, third and fourth leads 12, 13 and 14 and the semiconductor element 20 is not specifically limited.

### Second Embodiment

FIGS. 27 to 31 show a semiconductor device according to second embodiment of the present disclosure. For a semiconductor device A20 of the present embodiment, the first resin surface 41 is formed with a recessed region 411 different from those in the examples described above.

The recessed region 411 of the present embodiment is a rectangular or U-shaped groove. The recessed region 411 of the present embodiment includes a pair of wall surfaces 4115 and 4116 and a groove bottom 4117.

The wall surfaces 4115 and 4116 are parallel to the y-z plane. The wall surfaces 4115 and 4116 are perpendicular to the end region 412 and the groove bottom 4117. In a different example, the wall surfaces 4115 and 4116 may be inclined relative to the end region 412.

The groove bottom 4117 is located between the wall surfaces 4115 and 4116 in the x direction. In the illustrated example, the groove bottom 4117 is a flat surface. In a different example, the groove bottom 4117 may be curved at least partly. In the present embodiment, the groove bottom 4117 is the deepest portion of the recessed region 411.

The semiconductor device A20 according to the present embodiment is surface mountable. In addition, the presence of the recessed region 411 of the present embodiment serves to increase each creepage distance between a first terminal portion 112 and a second terminal portion 122 along the first resin surface 41. As the present embodiment indicates, the recessed region 411 is not limited to a V-shaped groove as in the semiconductor device A10 and may alternatively be a rectangular or U-shaped groove.

### Third Embodiment

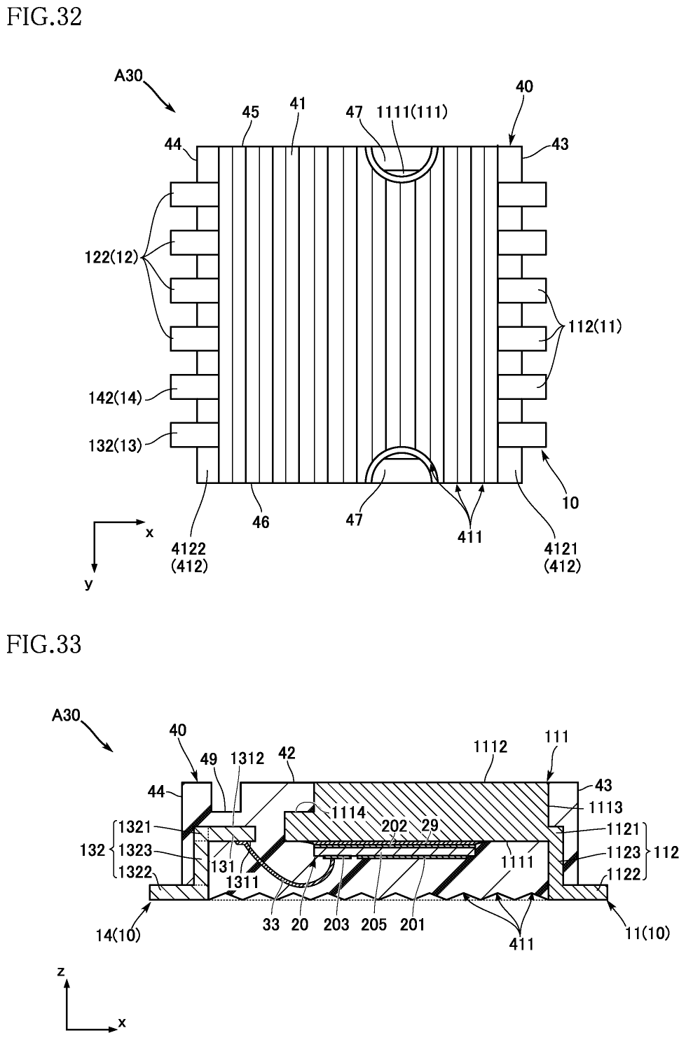

FIGS. 32 and 33 show a semiconductor device according to a third embodiment of the present disclosure. For a semiconductor device A30 of the present embodiment, the first resin surface 41 includes a plurality of recessed regions 411.

The recessed regions 411 extend from the fifth resin surface 45 to the sixth resin surface 46 as viewed in the z direction. Each recessed region 411 of the semiconductor device A30 is a V-shaped groove as in the semiconductor device A10. Thus, each recessed region 411 includes a valley 4111, a first slope 4112, and a second slope 4113. The recessed regions 411 are arranged side by side in the x direction. While the recessed regions 411 are parallel (or substantially parallel) to each other in the illustrated example, the recessed regions 411 are not required to be parallel to each other. In addition, while the recessed regions 411 in the illustrated example are adjacent to each other without a gap in the x direction, the recessed regions 411 may be arranged at spaced intervals in the x direction. In such a case, a flat region is formed between each two recessed regions 411 next to each other in the x direction.

The semiconductor device A30 according to the present embodiment is surface mountable. In addition, the presence of the recessed regions 411 of the present embodiment serves to increase each creepage distance between a first terminal portion 112 and a second terminal portion 122 along the first resin surface 41. As the present embodiment indicates, the number of recessed regions 411 to be provided is not limited to one.

### First Variation of Third Embodiment

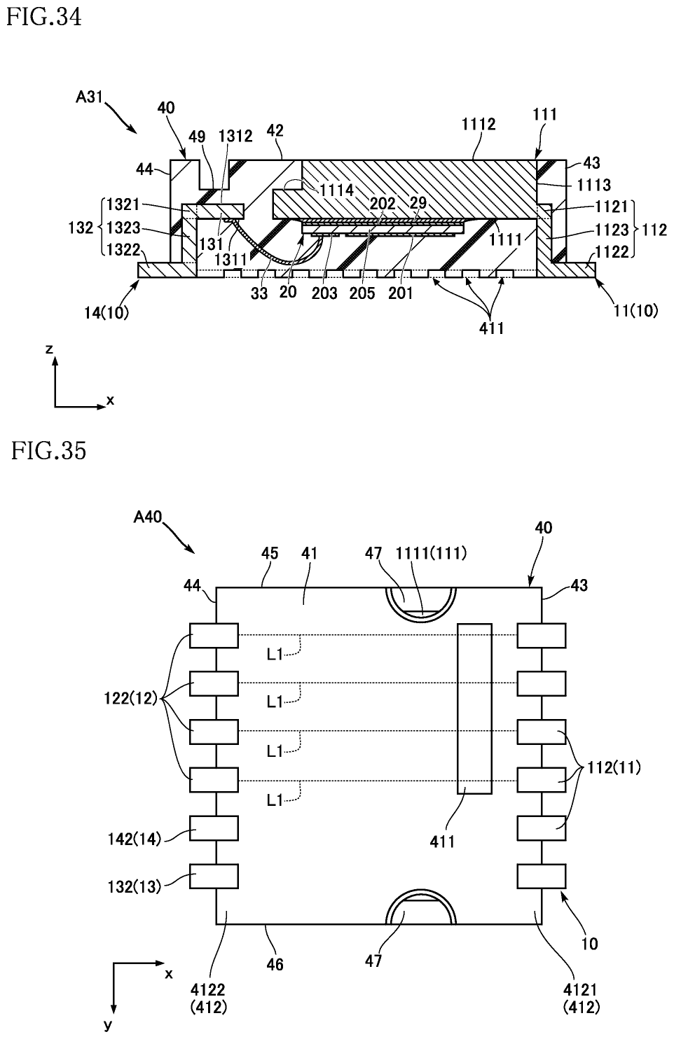

FIG. 34 shows a variation of the semiconductor device A30. For a semiconductor device A31 according to the present variation, each of the plurality of recessed regions 411 is a rectangular groove as in the semiconductor device A30. Thus, each recessed region 411 includes a pair of wall surfaces 4115 and 4116 and a groove bottom 4117. While the recessed regions 411 are arranged at equal intervals in the x direction, the intervals are not required to be equal.

The semiconductor device A31 according to the present variation is surface mountable. In addition, the presence of the recessed region 411 of the present variation serves to increase each creepage distance between a first terminal portion 112 and a second terminal portion 122 along the first resin surface 41.

### Fourth Embodiment

FIG. 35 shows a semiconductor device according to a fourth embodiment of the present disclosure. For a semiconductor device A40 of the present embodiment, the recessed region 411 does not extend from the fifth resin surface 45 to the sixth resin surface 46 as viewed in the z direction.

In the illustrated example, the recessed region 411 as viewed in the z direction is rectangular. In a different example, however, the recessed region 411 may be polygonal, circular, elliptical, oval, or annular as viewed in Z direction. The extent of the recessed region 411 is not limited to the one in the illustrated example. The recessed region 411 may have any extent overlapping with the imaginary lines L1 as viewed in z direction. In addition, while the recessed region 411 is spaced apart from both of the two recesses 47, the recessed region 411 may alternatively be formed to connect the two recesses 47. In such a case, the depth of the recessed region 411 needs to be shallower than the recesses 47 so as not to expose the semiconductor element 20 from the sealing resin 40.

The semiconductor device A40 according to the present embodiment is surface mountable. According to the present embodiment, the recessed 411 region overlaps with the imaginary lines L1 as viewed in the z direction, so that each creepage distance can be increased between a first terminal portion 112 and a second terminal portion 122 along the first resin surface 41. As the present embodiment indicates, the recessed region 411 is not limited in extent or shape (the configuration of the recess) as long as the recessed region 411 overlaps with the imaginary lines L1 as viewed in the z direction.

In each embodiment and variation described above, the die pad portion 111 and the first terminal portions 112 are integral. In an alternative example, however, the first terminal portions 112 may be separated from the die pad portion 111. In such an example, additional connecting members may be used to electrically connect the first terminal portions 112 and the semiconductor element 20 mounted on the die pad portion 111.

The semiconductor device according to the present disclosure is not limited to the above-described embodiments. Various modifications in design may be made freely in the specific structure of each part of the semiconductor device according to the present disclosure. The present disclosure includes embodiments described in the following clauses.

Clause 1.

A semiconductor device comprising:
a semiconductor element;
a conductive member including a die pad portion, a first terminal portion, and a second terminal portion; and
a sealing resin covering a portion of the conductive member and the semiconductor element,
wherein the sealing resin includes a first resin surface facing in a first sense of a thickness direction of the sealing resin, a second resin surface facing in a second sense of the thickness direction, a third resin surface facing in a first sense of a first direction perpendicular to the thickness direction, and a fourth resin surface facing in a second sense of the first direction,
the die pad portion includes: a mounting surface facing in the first sense of the thickness direction and on which the semiconductor element is mounted; and an exposed surface facing in the second sense of the thickness direction and exposed from the second resin surface,
the first terminal portion is bent toward a side in the first sense of the thickness direction and exposed from the third resin surface,
the second terminal portion is bent toward the side in the first sense of the thickness direction and exposed from the fourth resin surface,
the first resin surface includes a recessed region recessed in the thickness direction toward the second resin surface, and
the recessed region overlaps with an imaginary line connecting the first terminal portion and the second terminal portion as viewed in the thickness direction.

Clause 2.

The semiconductor device according to Clause 1, wherein the sealing resin includes a fifth resin surface facing in a first sense of a second direction perpendicular to the thickness direction and the first direction, and a sixth resin surface facing in a second sense of the second direction, and
the recessed region extends from the fifth resin surface to the sixth resin surface as viewed in the thickness direction.

Clause 3.

The semiconductor device according to Clause 2, wherein the recessed region includes: a valley that linearly extends from the fifth resin surface to the sixth resin surface as viewed in the thickness direction; and a first slope that meets the valley from a side in the first sense of the first direction and is inclined relative to the second resin surface, and
the first slope is inclined such that a depth of the recessed region increases with approach toward the valley.

Clause 4.

The semiconductor device according to Clause 3, wherein the recessed region includes a second slope that meets the valley from a side in the second sense of the first direction and is inclined relative to the second resin surface, and
the second slope is inclined such that the depth of the recessed region increases with approach toward the valley.

Clause 5.

The semiconductor device according to Clause 2, wherein the recessed region includes a pair of wall surfaces and a groove bottom located between the pair of wall surfaces in the first direction.

Clause 6.

The semiconductor device according to any one of Clauses 2 to 5, wherein the first resin surface includes a plurality of the recessed regions arranged side by side in the first direction.

Clause 7.

The semiconductor device according to any one of Clauses 1 to 6, wherein the first resin surface includes an end region on either side of the recessed region in the first direction, and the end region is flat.

Clause 8.

The semiconductor device according to Clause 7, wherein the first terminal portion includes a first section and a second section,
the first section is located closer than the second section to the die pad portion in the first direction and covered with the sealing resin, and
the second section protrudes from the second resin surface and is exposed at the end region.

Clause 9.

The semiconductor device according to Clause 8, wherein the first terminal portion includes a third section connected to the first section and the second section, and
the third section is perpendicular to each of the first section and the second section and extends in the thickness direction.

Clause 10.

The semiconductor device according to Clause 8 or 9, wherein the second terminal portion includes a fourth section and a fifth section,
the fourth section is located closer than the fifth section to the die pad portion in the first direction and covered with the sealing resin, and
the fifth section protrudes from the fourth resin surface and is exposed at the end region.

Clause 11.

The semiconductor device according to Clause 10, wherein the second terminal portion includes a sixth section connected to the fourth section and the fifth section, and
the sixth section is perpendicular to each of the fourth section and the fifth section and extends in the thickness direction.

Clause 12.

The semiconductor device according to Clause 10 or 11, wherein the first terminal portion is connected at the first section to the die pad portion, and
the second terminal portion is spaced apart from the die pad portion.

Clause 13.

The semiconductor device according to Clause 12, further comprising a connecting member bonded to the semiconductor element,
wherein the connecting member is covered with the sealing resin.

Clause 14.

The semiconductor device according to Clause 13, wherein a deepest portion of the recessed region does not overlap with the connecting member as viewed in the thickness direction.

Clause 15.

The semiconductor device according to Clause 14, wherein the depth of the recessed region at the deepest portion is greater than a separation distance between the connecting member and the end region in the thickness direction.

Clause 16.

The semiconductor device according to any one of Clauses 10 to 15, wherein the depth of the recessed region at a deepest portion is greater than a thickness of each of the second section and the fifth section.

Clause 17.

The semiconductor device according to any one of Clauses 1 to 16, wherein the semiconductor element comprises a switching element or a diode.

REFERENCE NUMERALS

A10 to A16, A20, A30, A31, A40: Semiconductor
10: Conductive member 11: First lead
12: Second lead 13: Third lead
14: Fourth lead 20: Semiconductor element
29: Bonding layer 31: Connecting member
32: Connecting member 33: Connecting member
40: Sealing resin 41: First resin surface
42: Second resin surface 43: Third resin surface
44: Fourth resin surface 45: Fifth resin surface
46: Sixth resin surface 47: Recess
48: Protrusion 49: Groove
91: Heat sink 92: Circuit board
111: Die pad portion 112: First terminal portion
121: Pad portion 122: Second terminal portion
131: Pad portion 132: Third terminal portion
141: Pad portion 142: Fourth terminal portion
201: First electrode 202: Second electrode
203: Third electrode 205: Semiconductor layer
411: Recessed region 412: End region
919: Sheet material 921: Solder
1111: First-lead obverse surface
1112: First-lead reverse surface
1113: First-lead side surface
1114: First intermediate surface
1121: First section 1122: Second section
1123: Third section 1211: Second-lead obverse surface
1212: Second-lead reverse surface 1221: Fourth section
1222: Fifth section 1223: Sixth section
1311: Third-lead obverse surface
1312: Third-lead reverse surface
1321: Seventh section 1322: Eighth section
1323: Ninth section 1411: Fourth-lead obverse surface
1412: Fourth-lead reverse surface 1421: Tenth section
1422: Eleventh section 1423: Twelfth section
4111: Valley 4112: First slope
4113: Second slope 4115: Wall surface
4116: Wall surface 4117: Groove bottom
4121: First region 4122: Second region
L1: Imaginary line

1. A semiconductor device comprising:
a semiconductor element;
a conductive member including a die pad portion, a first terminal portion, and a second terminal portion; and
a sealing resin covering a portion of the conductive member and the semiconductor element,
wherein the sealing resin includes a first resin surface facing in a first sense of a thickness direction of the sealing resin, a second resin surface facing in a second sense of the thickness direction, a third resin surface facing in a first sense of a first direction perpendicular to the thickness direction, and a fourth resin surface facing in a second sense of the first direction,
the die pad portion includes: a mounting surface facing in the first sense of the thickness direction and on which the semiconductor element is mounted; and an exposed surface facing in the second sense of the thickness direction and exposed from the second resin surface,
the first terminal portion is bent toward a side in the first sense of the thickness direction and exposed from the third resin surface,
the second terminal portion is bent toward the side in the first sense of the thickness direction and exposed from the fourth resin surface,
the first resin surface includes a recessed region recessed in the thickness direction toward the second resin surface, and
the recessed region overlaps with an imaginary line connecting the first terminal portion and the second terminal portion as viewed in the thickness direction.

2. The semiconductor device according to claim 1, wherein the sealing resin includes a fifth resin surface facing in a first sense of a second direction perpendicular to the thickness direction and the first direction, and a sixth resin surface facing in a second sense of the second direction, and
the recessed region extends from the fifth resin surface to the sixth resin surface as viewed in the thickness direction.

3. The semiconductor device according to claim 2, wherein the recessed region includes: a valley that linearly extends from the fifth resin surface to the sixth resin surface as viewed in the thickness direction; and a first slope that meets the valley from a side in the first sense of the first direction and is inclined relative to the second resin surface, and
the first slope is inclined such that a depth of the recessed region increases with approach toward the valley.

4. The semiconductor device according to claim 3, wherein the recessed region includes a second slope that meets the valley from a side in the second sense of the first direction and is inclined relative to the second resin surface, and
the second slope is inclined such that the depth of the recessed region increases with approach toward the valley.

5. The semiconductor device according to claim 2, wherein the recessed region includes a pair of wall surfaces and a groove bottom located between the pair of wall surfaces in the first direction.

6. The semiconductor device according to claim 2, wherein the first resin surface includes a plurality of the recessed regions arranged side by side in the first direction.

7. The semiconductor device according to claim 1, wherein the first resin surface includes an end region on either side of the recessed region in the first direction, and
the end region is flat.

8. The semiconductor device according to claim 7, wherein the first terminal portion includes a first section and a second section,
the first section is located closer than the second section to the die pad portion in the first direction and covered with the sealing resin, and
the second section protrudes from the second resin surface and is exposed at the end region.

9. The semiconductor device according to claim 8, wherein the first terminal portion includes a third section connected to the first section and the second section, and
the third section is perpendicular to each of the first section and the second section and extends in the thickness direction.

10. The semiconductor device according to claim 8, wherein the second terminal portion includes a fourth section and a fifth section,
the fourth section is located closer than the fifth section to the die pad portion in the first direction and covered with the sealing resin, and
the fifth section protrudes from the fourth resin surface and is exposed at the end region.

11. The semiconductor device according to claim 10, wherein the second terminal portion includes a sixth section connected to the fourth section and the fifth section, and
the sixth section is perpendicular to each of the fourth section and the fifth section and extends in the thickness direction.

12. The semiconductor device according to claim 10, wherein the first terminal portion is connected at the first section to the die pad portion, and
the second terminal portion is spaced apart from the die pad portion.

13. The semiconductor device according to claim 12, further comprising a connecting member bonded to the semiconductor element,
wherein the connecting member is covered with the sealing resin.

14. The semiconductor device according to claim 13, wherein a deepest portion of the recessed region does not overlap with the connecting member as viewed in the thickness direction.

15. The semiconductor device according to claim 14, wherein the depth of the recessed region at the deepest portion is greater than a separation distance between the connecting member and the end region in the thickness direction.

16. The semiconductor device according to claim 10, wherein the depth of the recessed region at a deepest portion is greater than a thickness of each of the second section and the fifth section.

17. The semiconductor device according to claim 1, wherein the semiconductor element comprises a switching element or a diode.
